(19) United States
(12) Patent Application Publication
(10) Pub. No.: US 2023/0332328 A1
(43) Pub. Date: Oct. 19, 2023

(54) Reaction Device for Improving Epitaxial Growth Uniformity

(71) Applicant: Shanghai Huali Integrated Circuit Corporation, Shanghai (CN)

(72) Inventors: Hui Wang, Shanghai (CN); Huojin Tu, Shanghai (CN); Jiaqi Hong, Shanghai (CN); Jun Tan, Shanghai (CN); Jingxun Fang, Shanghai (CN)

(73) Assignee: Shanghai Huali Integrated Circuit Corporation, Shanghai (CN)

(21) Appl. No.: 18/125,877

(22) Filed: Mar. 24, 2023

(30) Foreign Application Priority Data
Apr. 15, 2022 (CN) 202210399190.3

(51) Int. Cl. C30B 25/14; C30B 25/16; C23C 16/455

(52) U.S. Cl. CPC C30B 25/14; C23C 16/45563; C30B 25/165

(57) ABSTRACT

The present application provides a reaction device for improving epitaxial growth uniformity, provided with a main inject port on one side and an exhaust port on the other side, wherein a base is provided between the main inject port and the exhaust port; the reaction cavity is provided with first and second inject pipes; the length directions of the first and second inject pipes are perpendicular to a connecting line between the main inject port and the exhaust port; the lengths of the first and second inject pipes are both equal to the radius of the base; the first and second inject pipes are located in a straight line along the length directions; the first and second inject pipes are each provided with a plurality of holes; and the plurality of holes on the first and second inject pipes are located above the wafer placed on the base.

### CROSS-REFERENCE TO RELATED APPLICATIONS

This application claims priority to Chinese patent application No. 202210399190.3, filed on Apr. 15, 2022, the disclosure of which is incorporated herein by reference in its entirety.

### TECHNICAL FIELD

The present application relates to the technical field of semiconductors, in particular to a reaction device for improving epitaxial growth uniformity.

### BACKGROUND

In the advanced process, vapor deposition is used to implement epitaxial layer growth. A reaction process includes injecting reaction gases into a reaction chamber via the same inject port, where the gases react and deposit on the surface of a silicon wafer. The silicon wafer is placed on a rotating base in the reaction chamber. The grown epitaxial layer often has the problem of uniformity, resulting in a donut map. Referring to FIG. 1, FIG. 1 is a schematic diagram of a donut difference in the thickness of an epitaxial layer grown on a wafer after epitaxial growth in the prior art. A common method for solving the problem of epitaxial growth uniformity is adding an additional inject port at a position perpendicular to the direction of the inject port to supplement the reaction gas. As the impact of a flow at an exhaust port on the added x-flow on the wafer ranges only at the radius of 140-150 nm, the epitaxial growth uniformity may be improved to a specific extent, while the effect of improving the uniformity at the radius of 120-140 nm is unsatisfactory, and the phenomenon of a donut map still exists.

### BRIEF SUMMARY

In view of the above defect in the prior art, the objective of the present application is to provide a reaction device for improving epitaxial growth uniformity, so as to solve the problem of nonuniform epitaxial growth on a wafer which results in device performance degradation in the prior art.

In order to achieve the above objective and other related objectives, the present application provides a reaction device for improving epitaxial growth uniformity, at least including:
a reaction cavity for epitaxial growth, the reaction cavity being provided with a main inject port on one side thereof and an exhaust port on the other side thereof opposite to the main inject port, wherein a base for placing a wafer is provided between the main inject port and the exhaust port;
the reaction cavity is provided with first and second inject pipes on two sides of the base; the length directions of the first and second inject pipes are perpendicular to a connecting line between the main inject port and the exhaust port; the shape of the base is circular; the lengths of the first and second inject pipes are both equal to the radius of the base; the first and second inject pipes are located in a straight line along the length directions thereof;
the first and second inject pipes are each provided with a plurality of holes along respective length directions; and the plurality of holes on the first and second inject pipes are located above the wafer placed on the base.

In some examples, the first and second inject pipes are each provided with three holes, and the three holes are a first hole, a second hole, and a third hole.

In some examples, the first hole is located at a head end of each of the first and second inject pipes, and the head end is located above a central region of the wafer; the third hole is located on each of the first and second inject pipes above an edge region of the wafer; and the second hole is located between the first hole and the third hole on each of the first inject pipe and the second inject pipe.

In some examples, the first hole, the second hole, and the third hole are equally spaced apart from one another.

In some examples, the first hole is used to inject a reaction gas into the first and second inject pipes to improve epitaxial growth uniformity of the central region of the wafer; the second hole is used to inject a reaction gas into the first and second inject pipes to improve epitaxial growth uniformity of a sub-central region of the wafer; and the third hole is used to inject a reaction gas into the first and second inject pipes to improve epitaxial growth uniformity of the edge region of the wafer.

In some examples, the wafer is a wafer for making an NMOS or a PMOS.

In some examples, the reaction gas includes any one of SiH2Cl2, SiH4, GeH4, PH3, and HCL, and the flow rate of the reaction gas is 1-1000 sccm.

In some examples, the first and second inject pipes are also filled with a carrier gas, the carrier gas including at least one of hydrogen and nitrogen, and the flow rate of the carrier gas being 1-50 sm.

In some examples, an epitaxial temperature in the reaction chamber is 500-800°C, and a pressure is 1-100 torr.

As stated above, the reaction device for improving epitaxial growth uniformity of the preset application has the following beneficial effects: the present application aims at logic products of the advanced node, and improves the epitaxial growth uniformity by changing a gas circuit design, thus improving the electrical performance of the products.

### BRIEF DESCRIPTION OF THE DRAWINGS

FIG. 1 is a schematic diagram of a donut difference in the thickness of an epitaxial layer grown on a wafer after epitaxial growth in the prior art.

FIG. 2 is a top view of a reaction device for improving epitaxial growth uniformity according to the present application.

FIG. 3 is a side view of the reaction device for improving epitaxial growth uniformity according to the present application.

### DETAILED DESCRIPTION OF THE DISCLOSURE

The embodiments of the present application are described below using specific examples, and those skilled in the art can easily understand other advantages and effects of the present application from the contents disclosed in the Description. The present application can also be implemented or applied using other different specific embodiments, and various details in the Description can also be modified or changed based on different viewpoints and applications without departing from the spirit of the present application.

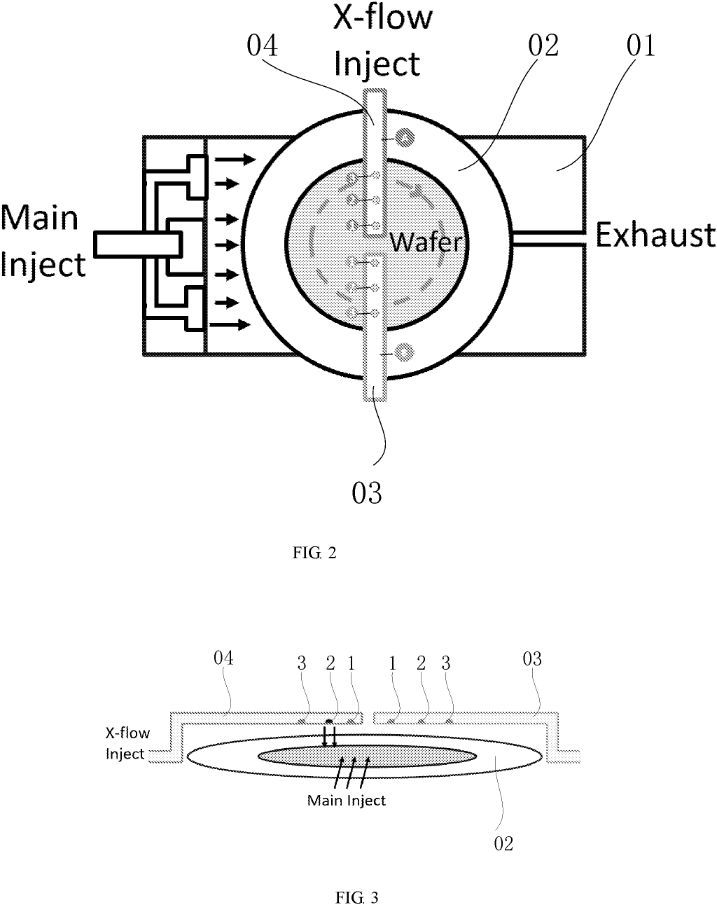

Please refer to FIGS. 2 and 3. It should be noted that the drawings provided in this embodiment are only used to illustrate the basic concept of the present application in a schematic way, so the drawings only show the components related to the present application rather than being drawn according to the number, shape and size of the components in actual implementation. The type, number and proportion of various components can be changed randomly during actual implementation, and the layout of components may be more complicated.

The present application provides a reaction device for improving epitaxial growth uniformity. Referring to FIG. 2, FIG. 2 is a top view of the reaction device for improving epitaxial growth uniformity according to the present application. The device at least includes:

a reaction cavity 01 for epitaxial growth, the reaction cavity 01 being provided with a main inject port on one side thereof and an exhaust port on the other side thereof opposite to the main inject port, wherein a base 02 for placing a wafer is provided between the main inject port and the exhaust port.

The reaction cavity 01 is provided with a first inject pipe 03 and a second inject pipe 04 on two sides of the base 02. The length directions of the first inject pipe 03 and the second inject pipe 04 are perpendicular to a connecting line between the main inject port and the exhaust port. The shape of the base 02 is circular. The lengths of the first inject pipe 03 and the second inject pipe 04 are both equal to the radius of the base 02. The first inject pipe 03 and the second inject pipe 04 are located in a straight line (X-flow inject) along the length directions thereof.

The first inject pipe 03 and the second inject pipe 04 are each provided with a plurality of holes along respective length directions. The plurality of holes on the first inject pipe 03 and the second inject pipe 04 are located above the wafer placed on the base.

The main inject port of the present application is also used for injecting a reaction gas.

In this embodiment of the present application, the first and second inject pipes are each provided with three holes, and the three holes are a first hole 1, a second hole 2, and a third hole 3.

Referring to FIG. 3, FIG. 3 is a side view of the reaction device for improving epitaxial growth uniformity according to the present application. In this embodiment of the present application, the first hole 1 is located at a head end of each of the first and second inject pipes, and the head end is located above a central region of the wafer; the third hole 3 is located on each of the first and second inject pipes above an edge region of the wafer; and the second hole 2 is located between the first hole 1 and the third hole 3 on each of the first inject pipe 03 and the second inject pipe 04.

In this embodiment of the present application, the first hole 1, the second hole 2, and the third hole 3 are equally spaced apart from one another.

In this embodiment of the present application, the first hole 1 is used to inject a reaction gas into the first and second inject pipes to improve epitaxial growth uniformity of the central region of the wafer; the second hole 2 is used to inject a reaction gas into the first and second inject pipes to improve epitaxial growth uniformity of a sub-central region of the wafer; and the third hole 3 is used to inject a reaction gas into the first and second inject pipes to improve epitaxial growth uniformity of the edge region of the wafer.

In this embodiment of the present application, the wafer is a wafer for making an NMOS or a PMOS.

In this embodiment of the present application, the reaction gas includes any one of SiH2Cl2, SiH4, GeH4, PH3, and HCL, and the flow rate of the reaction gas is 1-1000 sccm.

In this embodiment of the present application, the first and second inject pipes are also filled with a carrier gas, the carrier gas including at least one of hydrogen and nitrogen, and the flow rate of the carrier gas being 1-50 sm.

In s this embodiment of the present application, an epitaxial temperature in the reaction chamber is 500-800°C, and a pressure is 1-100 torr.

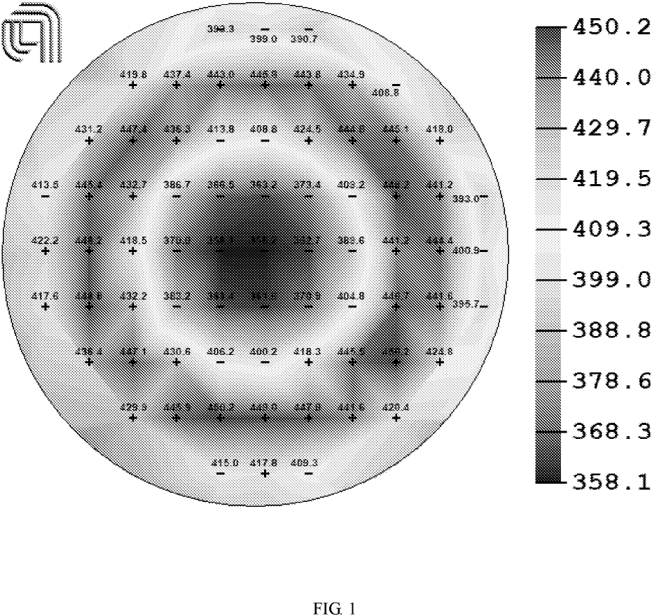

The present application can control an opening state of the hole on the pipe (the first inject pipe and the second inject pipe), so as to inject a specific gas to improve the uniformity of a specific region. The reaction gas may be injected into both pipes according to situations, so as to simultaneously improve an excessively grown epitaxial layer region and an insufficiently grown epitaxial layer region. For example, referring to FIG. 1, a current growth result shows a situation of excessive growth in the sub-central region and insufficiently grow the in the edge region. For this situation, according to the present application: an appropriate amount of HCL etching gas is injected into pipe A with only hole 2 opened, so as to improve an excessively grown region in the sub-central region of the wafer; and an appropriate amount of SiH2Cl2 growth gas is injected into pipe B with only hole 3 opened, so as to improve an insufficiently grown region in the edge region of the wafer.

The opening or closing of the holes on the pipe may be controlled to inject a specific reaction gas according to the situation, thus improving the epitaxial layer uniformity in specific regions such as the sub-central region, central region, or edge region of the wafer. Reaction gases having opposite effects may be injected into each of the two pipes, so as to simultaneously improve the excessive growth and insufficient growth in different regions. thus improving the overall epitaxial growth uniformity.

As stated above, the present application aims at logic products of the advanced node, and improves the epitaxial growth uniformity by changing a gas circuit design, thus improving the electrical performance of the products. Therefore, the present application effectively overcomes various defects in the prior art and thus has high industrial utilization value.

The above embodiment merely illustrates the principle and effect of the present application, rather than limiting the present application. Anyone skilled in the art can modify or change the above embodiment without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. A reaction device for improving epitaxial growth uniformity, at least comprising:
a reaction cavity for epitaxial growth, the reaction cavity being provided with a main inject port on one side thereof and an exhaust port on the other side thereof opposite to the main inject port, wherein a base for placing a wafer is provided between the main inject port and the exhaust port;
the reaction cavity is provided with first and second inject pipes on two sides of the base; length directions of the first and second inject pipes are perpendicular to a connecting line between the main inject port and the exhaust port; a shape of the base is circular; lengths of the first and second inject pipes are both equal to the radius of the base; the first and second inject pipes are located in a straight line along the length directions thereof;
the first and second inject pipes are each provided with a plurality of holes along respective length directions; and the plurality of holes on the first and second inject pipes are located above the wafer placed on the base.

2. The reaction device for improving epitaxial growth uniformity according to claim 1, wherein the first and second inject pipes are each provided with three holes, and the three holes are a first hole, a second hole, and a third hole.

3. The reaction device for improving epitaxial growth uniformity according to claim 2, wherein the first hole is located at a head end of each of the first and second inject pipes, and the head end is located above a central region of the wafer; the third hole is located on each of the first and second inject pipes above an edge region of the wafer; and the second hole is located between the first hole and the third hole on each of the first inject pipe and the second inject pipe.

4. The reaction device for improving epitaxial growth uniformity according to claim 3, wherein the first hole, the second hole, and the third hole are equally spaced apart from one another.

5. The reaction device for improving epitaxial growth uniformity according to claim 3, wherein the first hole is used to inject a reaction gas into the first and second inject pipes to improve epitaxial growth uniformity of the central region of the wafer; the second hole is used to inject a reaction gas into the first and second inject pipes to improve epitaxial growth uniformity of a sub-central region of the wafer; and the third hole is used to inject a reaction gas into the first and second inject pipes to improve epitaxial growth uniformity of the edge region of the wafer.

6. The reaction device for improving epitaxial growth uniformity according to claim 5, wherein the wafer is a wafer for making an NMOS or a PMOS.

7. The reaction device for improving epitaxial growth uniformity according to claim 5, wherein the reaction gas comprises any one of SiH2Cl2, SiH4, GeH4, PH3, and HCL, and a flow rate of the reaction gas is1-1000 sccm.

8. The reaction device for improving epitaxial growth uniformity according to claim 5, wherein the first and second inject pipes are also filled with a carrier gas, the carrier gas comprising at least one of hydrogen and nitrogen, and a flow rate of the carrier gas being 1-50 sm.

9. The reaction device for improving epitaxial growth uniformity according to claim 1, wherein an epitaxial temperature in the reaction chamber is 500-800° C., and a pressure is 1-100 torr.
